(19) United States
(12) Patent Application Publication
(10) Pub. No.: US 2026/0101773 A1
(43) Pub. Date: Apr. 9, 2026

(54) DEVICE PACKAGE WITH FLEXIBLY-ALIGNED LEAD FRAME CLIP

(71) Applicant: SEMICONDUCTOR COMPONENTS INDUSTRIES, LLC, Scottsdale, AZ (US)

(72) Inventors: NanNan CHEN, Jiang yin City (CN); XiaoYing YUAN, Suzhou (CN); Jie CHANG, Suzhou (CN); Keunhyuk LEE, Suzhou (CN)

(73) Assignee: SEMICONDUCTOR COMPONENTS INDUSTRIES, LLC, Scottsdale, AZ (US)

(21) Appl. No.: 18/908,504

(22) Filed: Oct. 7, 2024

(51) Int. Cl. H01L 23/00; H01L 21/56; H01L 23/495

(52) U.S. Cl. CPC H10W 70/424; H10W 70/481; H10W 74/016; H10W 70/456; H10W 72/07627; H10W 72/07636; H10W 72/634; H10W 72/652; H10W 90/766

(57) ABSTRACT

A package includes a semiconductor die disposed on a lead frame. A source contact pad is disposed on the semiconductor die. The package further includes a lead post shared by a plurality of leads that form external terminals of the package. The lead post has a clip-locking feature. A clip connects the source contact pad to the lead post. The clip has a key structure coupled to the clip-locking feature in the lead post.

### TECHNICAL FIELD

This description relates to packaging of semiconductor die and integrated circuits.

### BACKGROUND

A semiconductor package includes a metal, plastic, glass, or ceramic casing containing one or more semiconductor devices or integrated circuits. Individual components are fabricated on semiconductor wafers (commonly silicon, or silicon carbide wafers) before being diced into die, tested, and packaged. The package provides a means for connecting the semiconductor devices or integrated circuits to the external environment, such as printed circuit board, via leads such as lands, balls, or pins; and protection against threats such as mechanical impact, chemical contamination, and light exposure. With increasing demand for high-performance integrated circuits, improvements are needed in packaging technologies to address performance and reliability issues.

### SUMMARY

In an aspect, a package includes a semiconductor die disposed on a lead frame. A source contact pad is disposed on the semiconductor die. The package further includes a lead post shared by a plurality of leads that form external terminals of the package. The lead post has a clip-locking feature. A clip connects the source contact pad to the lead post. The clip has a key structure coupled to the clip-locking feature in the lead post.

In an aspect, a package includes a semiconductor die disposed at a variable location on a paddle in a lead frame. The semiconductor die includes a source contact pad. The package further includes a clip connecting the source contact pad to a lead post of the lead frame forming an external terminal of the package. The clip is aligned relative to the variable location of the semiconductor die on the paddle and the lead post.

In an aspect, a method includes disposing a semiconductor die at a variable location on a paddle in a lead frame. The semiconductor die has a source contact pad. The method further includes aligning a clip to connect a lead post of the lead frame to the source contact pad on the semiconductor die disposed at the variable location on the paddle.

The details of one or more implementations are set forth in the accompanying drawings and the description below. Other features will be apparent from the description and drawings, and from the claims.

### BRIEF DESCRIPTION OF THE DRAWINGS

FIG. 1 illustrates an example lead frame, according to at least one implementation.

FIGS. 2A and 2B illustrate views of an example clip that can be used in conjunction with the lead frame of FIG. 1.

FIGS. 3A-3E illustrate views of the lead frame of FIG. 1 at various stages of a process to configure a clip to connect a source contact pad of a semiconductor die to one or more external package leads of a semiconductor die package.

FIG. 4A illustrates a plan view of the lead frame of FIG. 1 depicting permitted ranges of the positions of a pair of spaced-apart keys of a clip.

FIG. 4B illustrates a cross-sectional view of a flexibly-aligned clip taken along direction A-A in FIG. 4A.

FIGS. 5A and 5B, FIGS. 6A and 6B, and FIGS. 7A and 7B illustrate examples of source contact pads disposed at various locations on a paddle in a lead frame.

FIG. 8A illustrates an example lead frame.

FIG. 8B illustrates a cross-sectional view of the lead frame of FIG. 8A taken along direction A-A in FIG. 8A.

FIG. 8C illustrates a cross-sectional view of the lead frame of FIG. 8A taken along direction B-B in FIG. 8A.

FIGS. 9A, 10A, 11A and 12A illustrate examples of semiconductor die and source contact pads disposed at various locations on a paddle in the lead frame of FIG. 8A.

FIGS. 9B, 10B, 11B, and 12B illustrate cross-sectional views of key structures connecting the semiconductor die and the source contact pads taken along directions A-A in FIGS. 9A, 10A, 11A and 12A, respectively.

FIGS. 9C, 10C, 11C, and 12C illustrate cross-sectional views of key structures connecting the semiconductor die and the source contact pads taken along directions B-B in FIGS. 9A, 10A, 11A and 12A, respectively.

FIG. 13 illustrates, in a plan view, a keyhole structure in a lead post of another example lead frame.

FIG. 14 A, 14B, 14C and 14D illustrate views of the lead post of FIG. 13, and keys of a clip post for various configurations of the semiconductor die and a paddle.

FIG. 15 illustrates yet another example lead frame.

FIG. 16 is a flow chart illustrating an example method for packaging a semiconductor die.

### DETAILED DESCRIPTION

Fabrication of a semiconductor device package may involve soldering or sintering to join or bond two components together. Soldering is a process of joining two metal surfaces together using a molten filler metal called solder. Sintering is a process of fusing particles together into one solid mass by using, for example, a combination of pressure and/or heat without melting the materials.

A semiconductor device package includes at least one semiconductor die mounted on a lead frame structure. In some implementations, the semiconductor device package may include multiple semiconductor dies of diverse types. For example, in a hybrid die package configuration, the semiconductor device package may include a silicon carbide (SiC) device die and a silicon device die.

In an example semiconductor device package, a semiconductor die is mounted, for example, on a first section of the lead frame, which includes a paddle or flag. The semiconductor die may, for example, be glued, sintered, and/or soldered onto the paddle or flag. A second section of the lead frame includes leads providing external electrical connections (external to the package) for an individual device or integrated circuit in the semiconductor die. Further, device contact pads (e.g., a gate contact pad, a signal sense contact pad, kelvin probe contact pad and a source contact pad, etc.) on the semiconductor die can be electrically connected to one or more of the leads. The leads, which extend to an outside of the package body, form external terminal pins that can be used to mount the package on a printed circuit board or terminal strip. In example implementations, the terminal pins can be installed in sockets or coupled (e.g., soldered, sintered) to a printed circuit board (PCB) or terminal strip.

There can be many package types used in various applications. Some are defined by international, national, or industry standards, while others are particular to an individual manufacturer. The number and configuration of external terminal pins of a package type may be defined by international, national, or industry standards.

The lead frame for a package may be manufactured by removing material from a flat plate or sheet made of copper, a copper-alloy, or an iron-nickel alloy. The techniques for material removal for making the lead frame can include etching (suitable for a high density of leads), or stamping (suitable for a low density of leads). A mechanical bending process can be applied after both techniques.

An example semiconductor die package can include a discrete semiconductor device, for example, a power transistor, a silicon carbide (SiC) MOSFET, or another device. In example implementations, the semiconductor die package can include a single semiconductor die or a hybrid plurality of dies of different types (e.g., a SiC die and a silicon (Si) die, etc.). The disclosure herein applies to both Surface Mount Device (SMD) packages and also Through Hole packages. In example implementations, the semiconductor die package may have x-y dimensions of several millimeters (e.g., about 5 mm to about 50 mm). The semiconductor die package also may have x-y dimensions of several millimeters (e.g., about 5 mm to about 50 mm).

In a power module package, a DAP (Die Attach Pad) is formed on the paddle or flag in the first section of a lead frame. The discrete semiconductor device (semiconductor die) can be glued, sintered, and/or soldered on the DAP. The second section of the lead frame includes leads that form the external terminals of the package. The leads may include lead posts that are connected to individual device contact pads (e.g., a gate contact pad and a signal sense contact pad, and a source contact pad) on the semiconductor die. In example implementations, wires are wire bonded (e.g., soldered) to connect some of the contact pads (e.g., gate contact pad, and signal sense contact pad) to individual lead posts on corresponding leads in the lead frame. In example implementations, the source contact pad may be connected by a clip to a lead post shared by one or more leads of the lead frame. The source contact pad in an example power module package may be connected by a clip to a lead post shared, for example, by two to ten leads (e.g., five leads) of the lead frame. A clip contact area with the device contact pad is larger than the contact areas obtained by wire bonding. This increased contact area allows for better heat dissipation from the die top to the lead frame, reducing the maximum junction temperature during operation. Further, a clip connection can have a better current carrying capability and a lower inductance than a wire bond.

This disclosure describes a flexibly-aligned clip and a lead frame with a clip-locking feature in a lead post of the lead frame. The flexibly-aligned clip may, for example, be a strip of metal having a generally rectangular shape. One end of the strip of metal may be attached (e.g., bonded, soldered) to contact the lead post. This end of the strip of metal may form (or be attached to) a clip post that is attached to the lead post. An opposite second end of the strip of metal (the flexibly-aligned clip tip) may be attached (e.g., soldered) to a device contact pad (e.g., the source contact pad) on the semiconductor die. The clip-locking feature in the lead post is configured to receive and hold the flexibly-aligned clip in a proper geometric position so that the flexibly-aligned clip tip is connected to, for example, the source contact pad of the semiconductor die disposed in the lead frame.

The flexibly-aligned clip and the clip-locking feature in the lead post of the lead frame may avoid issues with misalignment of the semiconductor die and the connecting clip during assembly of the package (e.g., during soldering operations or sintering operations). For example, if the semiconductor die or the connecting clip is shifted or rotated in position on the lead frame (e.g., over molten solder), the connecting clip may touch the source contact pad edge of the semiconductor die. This can be a problem during assembly, which can cause a final test fail or even a reliability test fail of the package. Use of the flexibly-aligned clip and the clip-locking feature in the lead post of the lead frame may avoid such issues by flexibly aligning the position of the connecting clip to compensate for the mis-positioning of the semiconductor die.

In accordance with the principles of the present disclosure, one end of a flexibly-aligned clip may include a pair of spaced-apart protrusions (e.g., keys, prongs, or stubs). The pair of space-apart protrusions (keys) may extend perpendicularly (e.g., in the z direction) to the plane (e.g., x-y plane) of the flexibly-aligned clip. The clip-locking feature in the lead post may include a hole structure (a keyhole structure) that is cut in the lead post and configured to receive the pair of spaced-apart protrusions (e.g., keys, prongs, or stubs) of the flexibly-aligned clip. The clip-locking feature is configured to hold the flexibly-aligned clip in a position properly aligned with, and in contact with, the source contact pad of the die.

In example implementations, the keyhole structure in the lead post may include at least a slot extending along a portion of a length of the lead post (e.g., in an x-direction). In example implementations, the keyhole structure in the lead post may include a first horizontal slot extending from an edge (e.g., a left edge) of the lead post toward a center of the lead post, and a second horizontal slot extending from an opposite edge (e.g., a right edge) of the lead post toward the center of the lead post (e.g., in a minus x-direction). The two horizontal slots may be separated by an uncut portion of width d at the center of the lead post. The slot (or slots) may be configured to receive the pair of spaced-apart protrusions (e.g., keys, prongs, or stubs) of the flexibly-aligned clip. The flexibly-aligned clip (the flexibly-aligned clip tip) may extend perpendicular (e.g., in a y direction) to the slot or slots with the pair of spaced-apart protrusions (e.g., keys, prongs or stubs) of the flexibly-aligned clip placed and locked in the slot or slots.

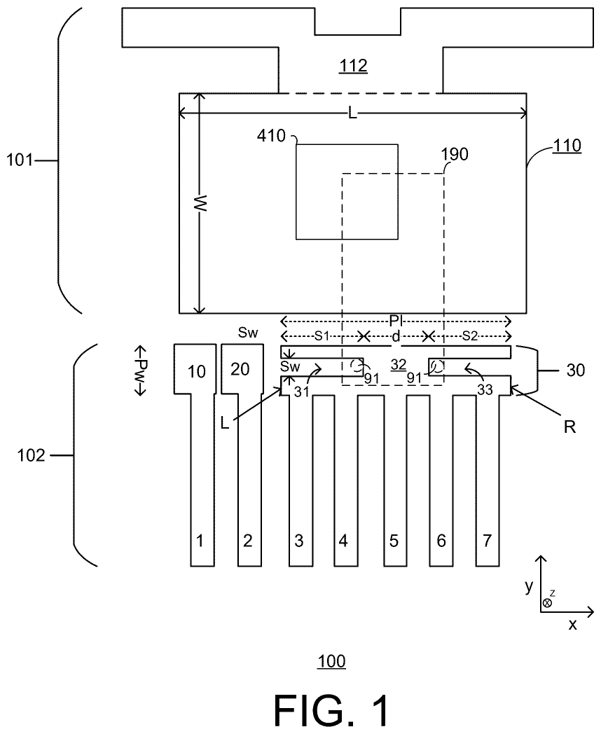

FIG. 1 shows a plan view of an example lead frame 100 that can be used in a semiconductor die package in accordance with the implementations described herein. Lead frame 100 may be fabricated from, for example, conductive materials such as a sheet of metal (e.g., copper, copper alloy, nickel or silver plated metal sheets, etc.). Lead frame 100 may include a first section 101 and a second section 102 as shown in at least FIG. 1.

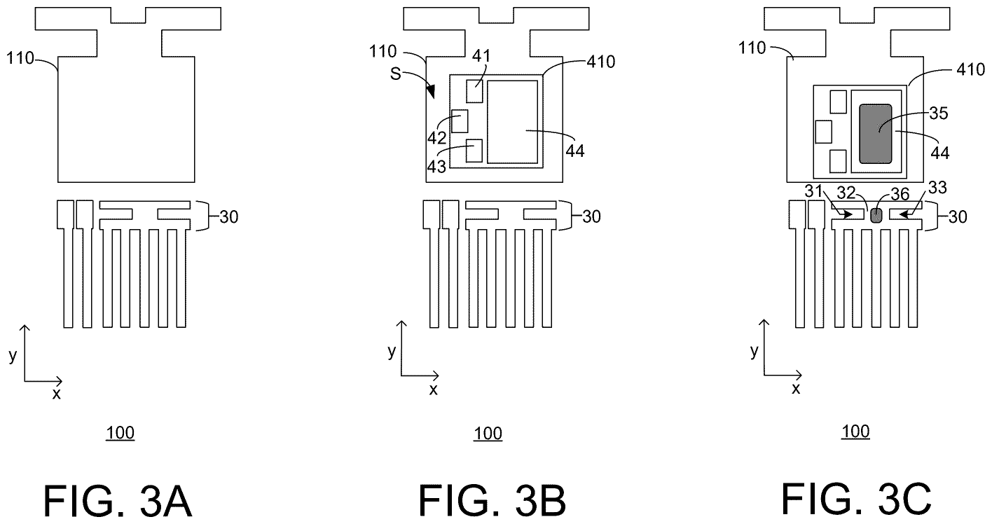

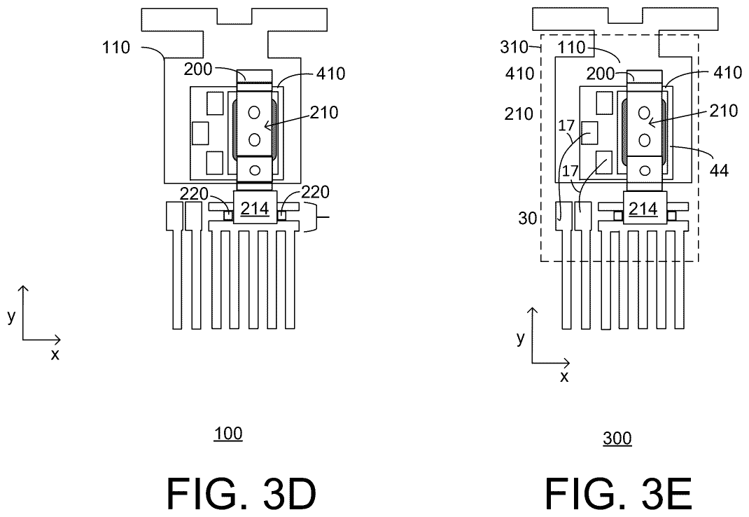

First section 101 of lead frame 100 may include a paddle 110 having, for example, a rectangular shape with a length L (e.g., in the x direction) and a width W (e.g., in the y direction). Paddle 110 may be configured to receive and hold the semiconductor die (e.g., die 410, FIG. 3B). In example implementations, paddle 110 may be coupled to a header portion (e.g., header 112) disposed above (e.g., in the y direction) the flag.

Header 112 may be electrically connected to the semiconductor die and may, for example, form an external drain or ground terminal for the semiconductor die in the package.

Second section 102 of lead frame 100 may include a plurality of leads (e.g., lead 1, lead 2, lead 3, lead 4, lead, 5, lead 6, and lead 7, etc.) that may, for example, form the external signal leads of the semiconductor die package. Although a specified number of leads are shown in FIG. 1, the number of leads can be different than shown in FIG. 1. The ends of the plurality of leads nearest to, for example, first section 101, may be attached or coupled to respective lead posts. For example, lead 1 is coupled to lead post 10 and lead 2 is coupled to lead post 20. Some of the leads may share a common lead post. In the example shown in FIG. 1, leads 3-7 may be commonly coupled to a lead post 30. The various lead posts may be coupled by wire bonds or clip connections to the device contact pads (e.g., gate contact pad, signal sense contact pad, Kelvin contact pad, and source contact pad, etc.) in the semiconductor die mounted on paddle 110.

FIG. 1 schematically shows, for example, a clip 190, which may form a clip connection between lead post 30 and semiconductor die 410 mounted on paddle 110. Clip 190 may, for example, be a rectangular sheet of metal. In FIG. 1, clip 190 is shown as a rectangle in dashed line. One end of clip 190 may have a pair of spaced-apart protrusions 91 extending (e.g., in the-z direction) perpendicular to the x-y plane of the clip. Clip 190 may be aligned, for example, in the x direction, such that clip 190 is placed over semiconductor die 410 mounted on paddle 110 by placing the spaced apart protrusions 91 in the keyhole structure (i.e., in slots 31 and 33) of the lead post 30 and sliding clip 190 in the x direction to the aligned position. Clip 190 may, for example, be soldered to a middle portion 32 of the lead post 30. This arrangement of the spaced-apart protrusions 91 in the keyhole structure constrains movement of the clip and prevents, for example, rotation of the clip in the x-y plane when the clip is, for example, being soldered to lead post 30.

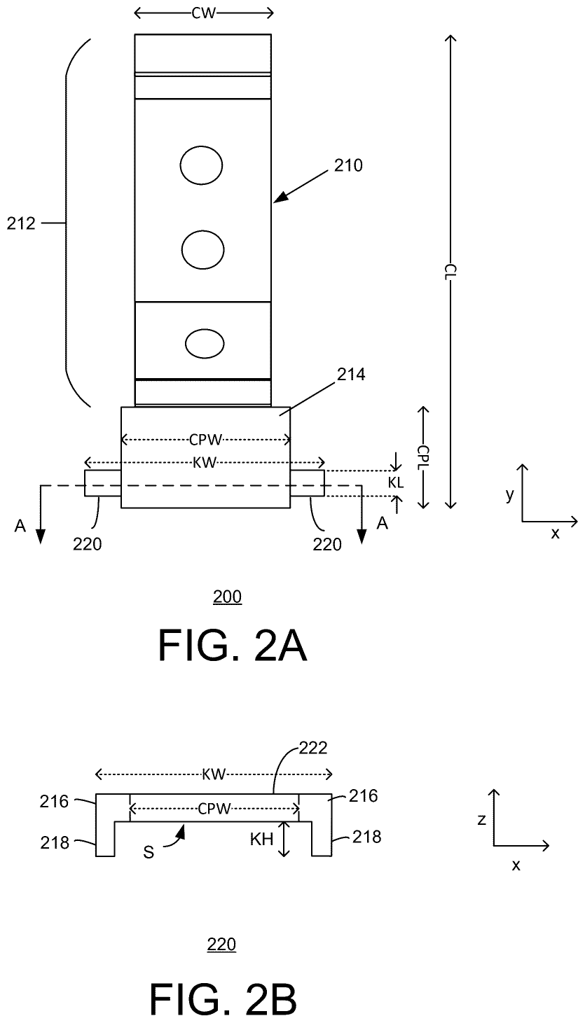

In example implementations, lead post 30 may be connected by clip (e.g., clip 200, FIGS. 2A and 2B) to the source contact pad on the semiconductor die (e.g., source contact pad 44 of semiconductor die 410, FIG. 3B) mounted on paddle 110.

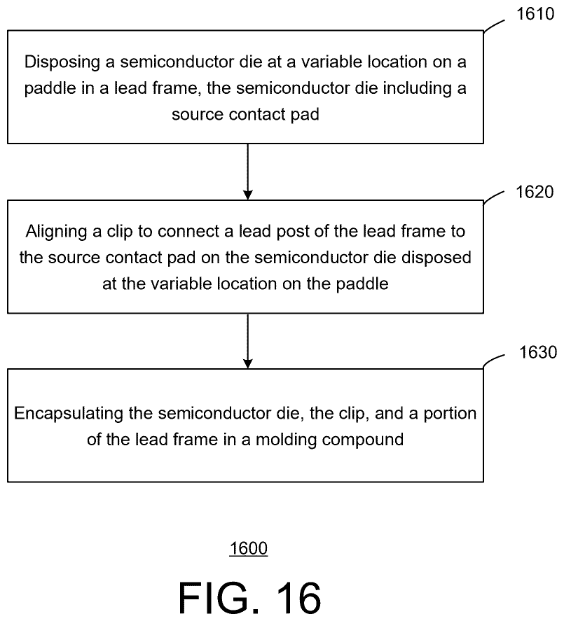

Although only shown with one semiconductor die in FIG. 1, more than one semiconductor die 410 can be attached to the paddle 110. The semiconductor die can be different types (e.g., hybrid die) and can be coupled in different ways within the lead frame 100 shown in FIG. 1. More examples of hybrid die scenarios are described in detail (e.g., before FIG. 1 and after FIG. 16).

FIGS. 2A and 2B illustrate a plan view and a side view of an example clip 200, respectively. Clip 200 may be flexibly aligned to connect the source contact pad of a semiconductor die to a lead post of a lead frame.

Clip 200 may, for example, be a strip of metal having a generally rectangular shape in an x-y plane. Clip 200 may have a length CL (e.g., in the y direction) and a width CW (e.g., in the x direction). A portion of clip 200 at one end of the strip of metal may be configured to be attached (e.g., soldered) to a device contact pad (e.g., the source contact pad) on the semiconductor die. The portion of clip 200 configured to be attached to the source contact pad on the semiconductor die may be called “the clip tip” (e.g., clip tip 212). An opposite second end of the strip of metal may be attached to, or form, a clip post 214. Clip post 214 may be configured to be attached (e.g., soldered) to the lead post of the lead frame. In example implementations, clip post 214 may have a length CPL (in the y direction) and a width CPW(in the x direction).

In example implementations, clip post 214 may include a clip-locking feature (e.g., a key structure 220) that in conjunction with the keyhole structure of the lead post 30 constrains or limits movement of clip 200. The clip locking feature may, for example, prevent movement of clip tip 212 from an initially set or aligned position on the source pad of the semiconductor die.

In example implementations, the clip-locking feature (e.g., key structure 220) may, for example, include a specific geometric arrangement of protrusions (e.g., keys, prongs, or stubs). In example implementations, the specific geometric arrangement of protrusions may, for example, include a pair of protrusions that are spaced apart in the x-direction. Such a pair of spaced-apart protrusions when placed in the slots 31 and 33 of the lead post (extending in the x direction) may allow initial movement of clip 210 in the x direction to place clip tip 212 in in contact with a device contact pad (e.g., source contact pad 44) on semiconductor die 410. The clip-locking feature (e.g., key structure 220) in conjunction with the keyhole structure may constrain or limit further movement of clip tip 212 away from its initially aligned position. The clip-locking feature (e.g., key structure 220) may, for example, restrict and/or limit translation of the clip tip in the y direction (based on the y direction width of the slots) and restrict rotation of the clip tip in the x-y plane. This restriction on rotation may be compared with the rotation of the clip tip that may be possible when the key structure is a single protrusion or no protrusion at all.

In example implementation, the clip locking features (e.g., keys, prongs, or stubs) may, for example, have cylindrical or rectangular cross-sections (in the x-y plane). The cylindrical or rectangular cross-sections may have dimensions matching the widths of the slots in the keyhole structure in post 30.

Key structure 220 may include a rectangular bar of metal 222 (FIG. 2B) that is attached to clip post 214 (or is a part of the strip of metal forming clip post 214). Key structure 220 may, for example, have a length KL (in the y direction) and a width KW (in the x direction). The width KW of key structure 220, may be the same as, less than, or greater than the width CPW of clip post 214. In the example implementation shown in FIG. 2A, the width KW of key structure 220 is, for example, greater than the width CPW of clip post 214.

As shown in FIG. 2B, key structure 220 may include a pair of spaced-apart keys, prongs, or stubs (e.g., keys 218) attached to the ends (e.g., ends 216) of the rectangular bar of metal 222 forming key structure 220. The pair of spaced-apart keys (e.g., keys 218) may extend perpendicularly (e.g., in the z direction) to the plane (e.g., x-y plane) of the clip 200.

Clip post 214 may be configured to be received and held by a pick-and-place assembly line tool to be placed in a proper geometric position (e.g., a flexibly aligned position) to connect, for example, the source contact pad of the semiconductor die disposed in the lead frame to the lead post (e.g., lead post 30, FIG. 1) in the lead frame (e.g., lead frame 100).

In example implementations, as shown in FIG. 1, lead post 30 in lead frame 100 may have a rectangular shape having a length Pl (in the x direction) and a width Pw (in the y direction). In example implementations, lead post 30 may include a keyhole structure configured to receive the pair of spaced-apart keys, prongs, or stubs of the flexibly-aligned clip (e.g., clip 200, FIGS. 2A and 2B). The keyhole structure may, for example, include a pair of slots 31, 33 extending inward along a portion of a length of the lead post from opposite edges of lead post 30 (e.g., in the x direction and minus x direction) toward a middle portion 32 of the lead post. In example implementations, the slots 31, 33 may have a rectangular shape. The pair of slots 31, 33 may allow the pair of spaced-apart keys, prongs or stubs received therein to be slid in the x direction allowing movement of clip 200 in the x-direction for flexible alignment with, for example, the source contact pad.

In example implementations, the slots in the keyhole structure may help limit rotational movement of the clip during assembly by constraining movement of the pair of spaced-apart keys, prongs, or stubs to be in the x direction of the slots.

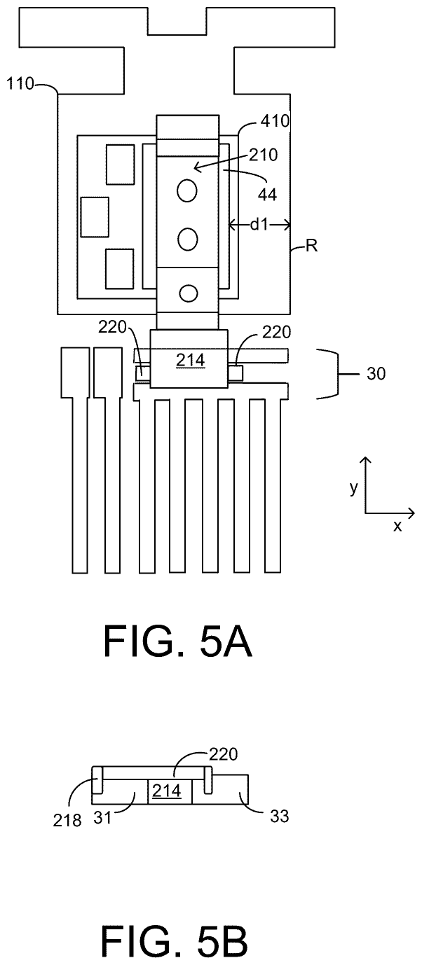

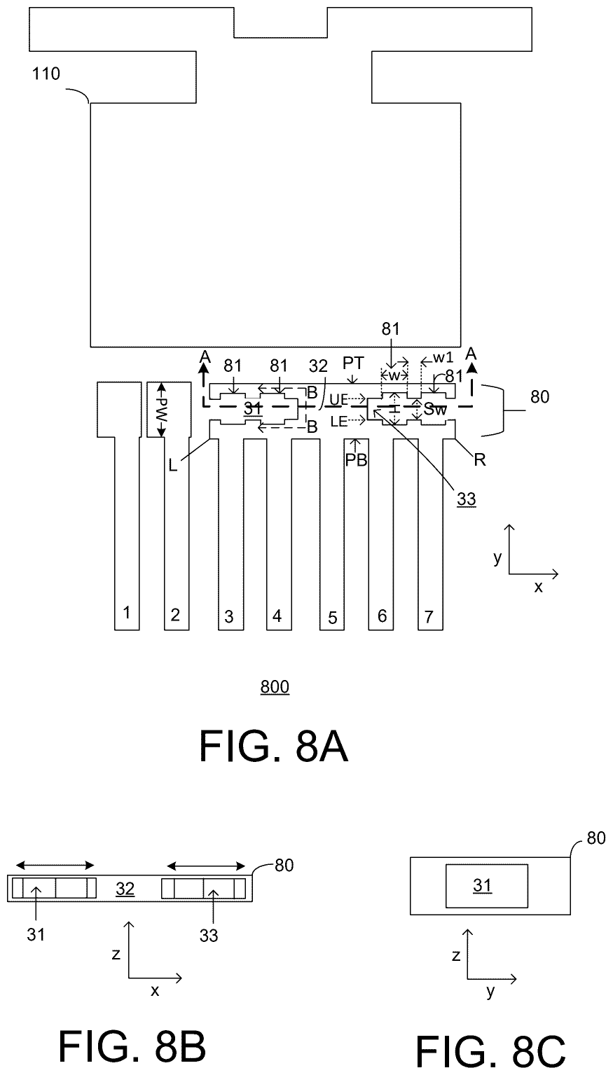

Slot 31 may, for example, extend (e.g., horizontally) from a left edge L of the lead post toward middle portion 32. Slot 33 may, for example, extend (e.g., horizontally) from a right edge R of the lead post toward uncut middle portion 32. In FIG. 1 and FIGS. 5A, 6A, and 7A (and FIGS. 8A-14), the left direction L and right direction R in the x direction refer to the left and the right of a viewer of the figures. Slot 31 and slot 33 may have lengths S1 and S2, respectively (in the x direction). Slot 31 and slot 33 each may have a same or a similar width Sw. Further, uncut middle portion 32 separating slot 31 and slot 33 may have a width d (in the x direction). In example implementations, the width Sw of each slot 31 and slot 33 may be about one third or less than a third of the width PW of lead post 30.

FIGS. 3A-3E illustrates views of lead frame 100 (FIG. 1) at various stages of a process to configure the flexibly-aligned clip 200 (FIG. 2A) to connect a source contact pad of a semiconductor die (e.g., semiconductor die 410) to package leads of a semiconductor die package 300. FIG. 3A shows a bare lead frame 100 at a start of the process. FIG. 3B shows a semiconductor die 410 disposed on paddle 110 of lead frame 100. Semiconductor die 410 may be disposed on a die attach pad (DAP) on a surface S of a paddle 110 of lead frame 100. Semiconductor die 410 may be attached to the DAP by a solder, an adhesive, or a sinter bond. Semiconductor die 410 may, for example, be a SiC metal-oxide-semiconductor field-effect transistor (MOSFET), an insulated-gate bipolar transistor (IGBT) or other power device die. A top surface of semiconductor die 410 may include various device contact pads, (e.g., gate contact pad 41, source sense contact pad 42, kelvin contact pad 43, and source contact pad 44, etc.).

FIG. 3C shows, for example, a layer of solder 35 that may be dispensed on source contact pad 44. Further, a layer of solder 36 may be dispensed on middle portion 32 of lead post 30. Solder 35 may be used for attaching one end of clip 200 (FIG. 2A) to source contact pad 44 of semiconductor die 130. Solder 36 may be used to attach a second end of clip 200 (FIG. 2A) to a lead post (e.g., lead post 30 connected to the package leads).

FIG. 3D shows, for example, flexibly-aligned clip 200 placed in position for connecting source contact pad 44 of semiconductor die 130 to lead post 30. In example implementations, clip post 214 may be placed over solder 36 on middle portion 32 of lead post 30 while the first portion (e.g., clip tip 212) of the strip of metal clip 210 is placed over solder 35 disposed on source contact pad 44 of the semiconductor die. Further, key structure 220 of clip post 214 may be aligned with the keyhole structure (e.g., slots 31 and 33) in lead post 30 such that the pair of keys 218 (not visible in FIG. 3D) are seated in slots 31 and 33.

FIG. 3E shows flexibly-aligned clip 200 connecting source contact pad 44 of semiconductor die 130 to lead post 30 after a solder reflow and cleaning step. Further, the various other device contact pads (e.g., gate contact pad 41, source sense contact pad 42, kelvin contact pad 43, and source contact pad 44, etc.) may be connected to corresponding lead posts by wire bonds 17. The semiconductor die 410 and portions of the lead frame may be then encapsulated in a molding compound to form a mold body 310 of semiconductor die package 300.

In example implementations, the pair of spaced-apart keys (e.g., keys 218) of clip post 214 can slide from one end of the respective slots (e.g., slots 31 and 33) in lead post 30 to an opposite end of the respective slots in the x direction. Accordingly, the flexibly-aligned clip tip (the strip of metal clip 210) attached to clip post 214 can have a permitted range of positions (in the x direction) above paddle 110 of lead frame 100. During assembly of the semiconductor die package, keys 218/clip post 214 can be slid within the allowed range to match any off-sets in the positioning of source contact pad 44 on paddle 110 (so that the flexibly-aligned clip tip is aligned with the source contact pad 44 on paddle 110)

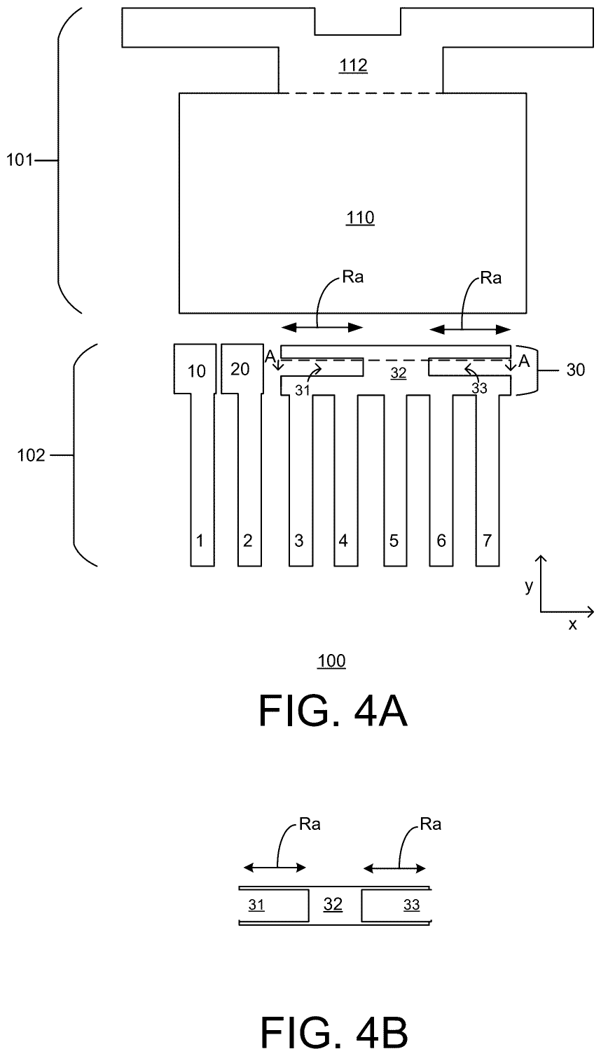

FIG. 4A shows a plan view of the lead frame of FIG. 1 in which permitted ranges of positions of the pair of spaced-apart keys (e.g., keys 218) in slots 31 and slot 33 are depicted by arrows Ra. FIG. 4B shows a cross-sectional view of the flexibly-aligned clip 200 (FIG. 2A) taken along direction A-A in FIG. 4A.

FIGS. 5A, 6A and 7A illustrate, in plan view, examples of clips 210 disposed at various locations on paddle 110 that are connected by flexibly-aligned clip 200 to lead post 30. FIGS. 5B, 6B and 7B show cross-sectional views of the flexibly-aligned clip 200 and lead post 30 of FIGS. 5A, 6A and 7A.

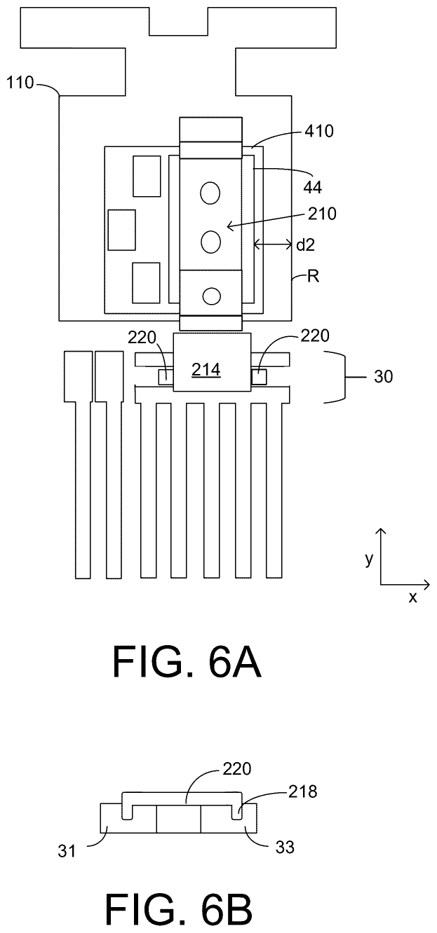

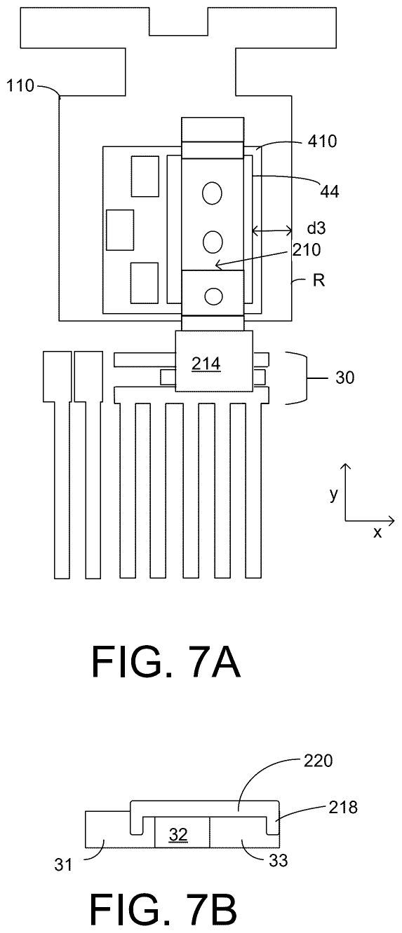

FIGS. 5A, 6A and 7A show, for example, in plan view, source contact pad 44 disposed at distance d1, d2 and d3 from a right edge R of paddle 110, respectively. Distance d1 may be greater than distance d2, which may be greater than distance d3. In each of these three instances, flexibly-aligned clip 200 is aligned with the source contact pads by sliding key structure 220 (that is attached clip post 214 and includes keys 218) in the keyhole structure (e.g., slots 31 and 33) in lead post 30 to place flexibly-aligned clip 200 over the source contact pad. For example, as shown in FIG. 5B, key structure 220 may be slid to a left most position so that flexibly-aligned clip 200 is directly above source contact pad 44 disposed at distance d1 from the right edge R of paddle 110 (FIG. 5A). Further, for example, as shown in FIG. 6B, key structure 220 may be slid to an intermediate position so that flexibly-aligned clip 200 is directly above source contact pad 44 disposed at distance d2 from the right edge R of paddle 110 (FIG. 6A). Further, for example, as shown in FIG. 7B, key structure 220 may be slid to a right most position so that flexibly-aligned clip 200 is directly above source contact pad 44 disposed at distance d3 from the right edge R of paddle 110 (FIG. 7A).

In example implementations, an optical inspection tool (not shown) may be used to determine the position of source contact pad 44 disposed on paddle 110 and a pick-and-place tool used to accordingly position flexibly-aligned clip 200 to connect source contact pad 44 to lead post 30.

In the embodiments described in the foregoing, for example, with reference to FIG. 1, lead post 30 is configured with a keyhole structure that includes a pair of rectangular slots (e.g., slots 31 and 33) that each have straight edges extending horizontally in the x direction on both the top and bottom edges of the rectangular openings of the slots.

In an example implementation, a keyhole structure of lead post 30 may be further configured with vertical notches or slots (e.g., extending in the y direction) that perpendicularly intersect the pair of rectangular slots (e.g., slots 31 and 33) that extend horizontally in the x direction.

FIG. 8A shows an example lead frame 800, in which a lead post 80 (like lead post 30 in the lead frame 100, FIG. 1) has a keyhole structure that includes a pair of horizontal slots (e.g., horizontal slots 31 and 33) extending horizontally inward in the x direction from the right edge R and the left edge L of the lead post toward a middle portion 32 of the lead post. The keyhole structure further includes a plurality of vertical rectangular slots (e.g., slots 81) extending from about a top edge PT of the lead post toward a bottom edge PB of the lead post. FIG. 8A shows, for example, two vertical slots 81 extending in the y direction perpendicularly across horizontal slot 31 and two vertical slots 81 extending in the y direction perpendicularly across horizontal slot 33. Slots 81 may have a height or length H (in the y direction) and a width w (in the x direction). The two adjacent vertical slots 81 crossing horizontal slot 33 may have an inter-slot spacing w1, and similarly the two adjacent vertical slots 81 crossing horizontal slot 31 may have an inter-slot spacing w1. The perpendicularly intersecting vertical slots 81 shape the edges to the horizontal slots 31 and 33 that extend in the y direction with steps in the vertical x direction. The vertical slots (for example, vertical slots 81) extend perpendicularly across both the upper edges (UE) and the lower edges (LE) of the horizontal slot 31 and horizontal slot 33.

The vertical notches or slots 81 in lead frame 800 have a height or length H in the y direction, which is greater than the width Sw (along the y axis) of slots 33 and 31 in frame 100. Thus, the keyhole structure in lead frame 800 can provide a larger y-axis clip position range than the range provided by the keyhole structure in frame 100. In example implementations, a height or length H of the vertical slots 81 in the y direction may be twice or more than twice the width Sw of slots 33 and 31 in the y direction.

FIG. 8B is a cross-sectional view of lead frame 800 taken along direction A-A in FIG. 8A, and FIG. 8C is a cross-sectional view of lead frame 800 taken along direction B-B in FIG. 8A.

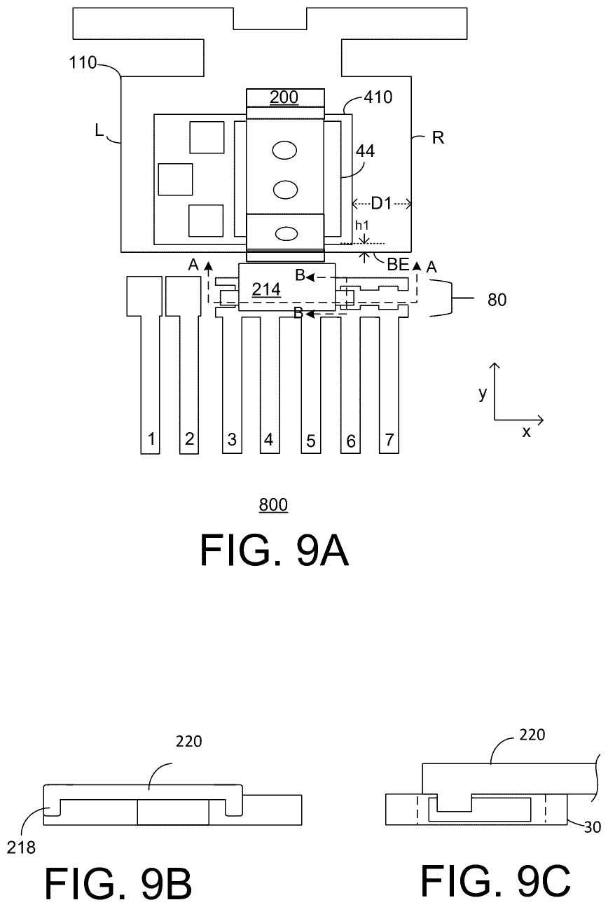

FIGS. 9A, 10A, 11A and 12A illustrate examples of semiconductor die 410 and source contact pads 44 disposed at various locations on paddle 110 of lead frame 800. The source contact pads 44 shown in these FIGS. are connected by flexibly-aligned clip 200 to lead post 80 of lead frame 800. FIGS. 9A, 10A, and 11A show, for example, semiconductor die 410 disposed at a distance D1 from a right edge R of paddle 110, and FIG. 12A shows, for example, semiconductor die 410 disposed at a distance D4 from a right edge R of paddle 110. Further, as shown in FIGS. 9A, 10A, 11A and 12A, semiconductor die 410 disposed at height h1, h2, h3 and h4, respectively, from a bottom edge BE of paddle 110.

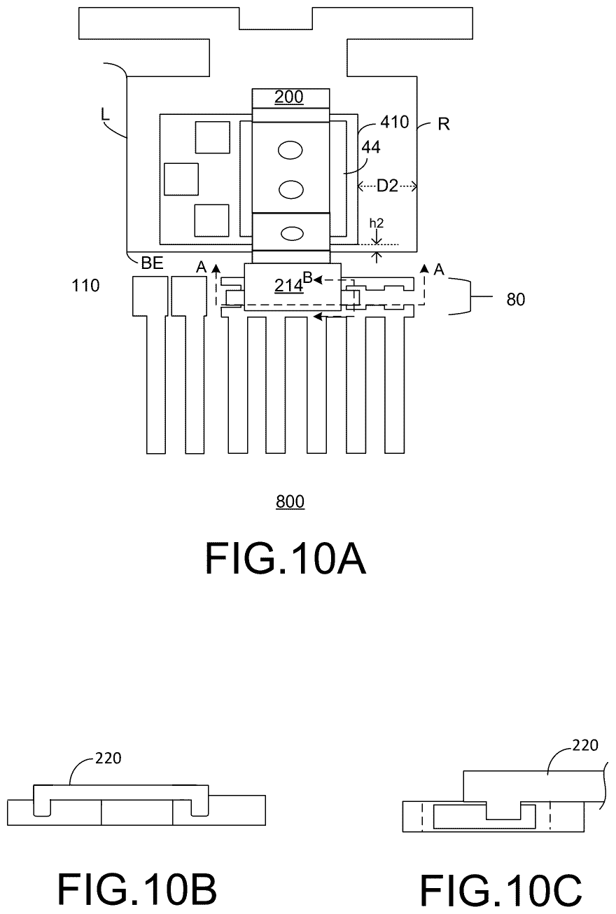

In each of these four instances (FIGS. 9A, 10A, 11A and 12A) flexibly-aligned clip 200 is aligned with the source contact pads by sliding key structure 220 (that is attached to clip post 214) in the keyhole structure in lead post 80. Keys 218 in key structure 220 (FIG. 2B) are placed in the keyhole structure in lead post 80 of lead frame 800 in appropriate slot positions (e.g., slots 31, 33, 81) to place flexibly-aligned clip 200 over the source contact pad. For example, for the instances of FIGS. 9A, 10A, and 11A, as shown in cross-sectional views in FIGS. 9B, 10B, and 11B, key structure 220 may be slid to a right most position in horizontal slot 31 and, as shown in FIG. 12B, to an intermediate position in horizontal slot 31. Further, for example, for the position shown in FIG. 9A, key structure 220 may be positioned at an up edge on the right in horizontal slot 31 as shown in FIG. 9C; and for the positions shown in FIGS. 10A, 11A and 12A, key structure 220 may be positioned at an up edge on the left in horizontal slot 31 as shown in FIGS. 10C, 11C and 12C, respectively.

In example implementations, an optical inspection tool (not shown) may be used to determine the position of source contact pad 44 disposed on paddle 110 and a pick-and-place tool used to accordingly position flexibly-aligned clip 200 to connect source contact pad 44 to lead post 80.

Example lead frame 800 (discussed above with references to FIG. 8A) has a keyhole structure in lead post 80 that includes a pair of horizontal slots (e.g., horizontal slots 31 and 33) extending horizontally inward in the x direction from the right edge R and the left edge L of the lead post toward a middle portion 32 of the lead post. The keyhole structure further includes a plurality of vertical rectangular slots (e.g., slots 81) from about a top edge PT of the lead post toward a bottom edge PB of the lead post. The vertical slots (for example, vertical slots 81) extend perpendicularly across both an upper edge and a lower edge of horizontal slot 31 and horizontal slot 33.

The vertical notches or slots 81 in frame 800 have a height or length H in the y direction, which is greater than the width Sw (along the y axis) of slots 33 and 31 in frame 800.

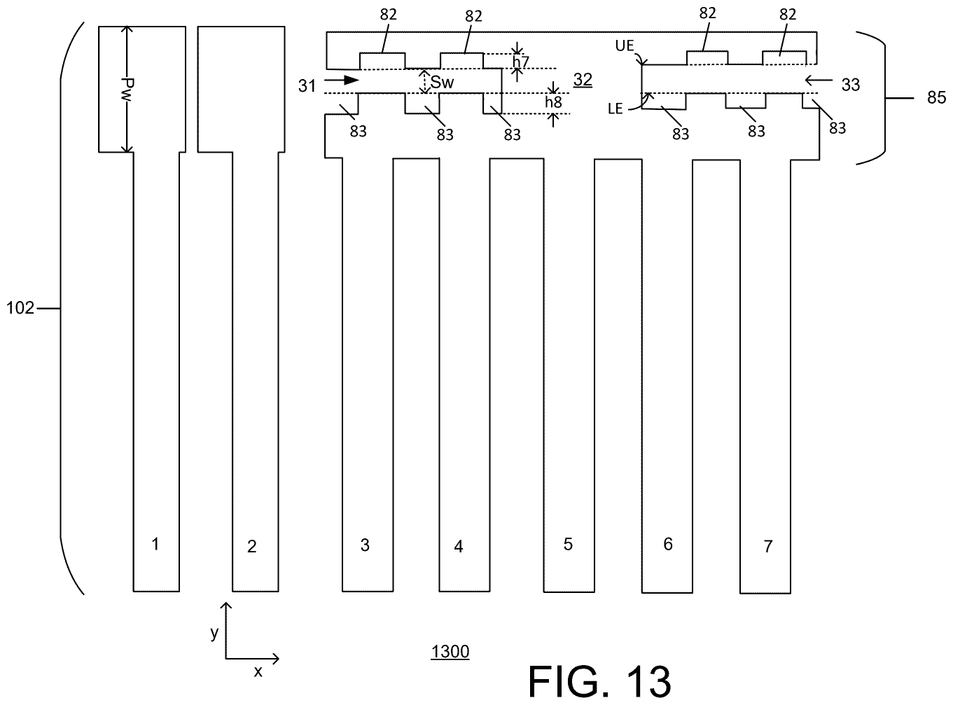

In other implementations, as shown in FIG. 13, the vertical slots (for example, vertical slots 82 and 83) may open into the horizontal slots, but do not extend perpendicularly across both an upper edge and a lower edge of the horizontal slot 31 and horizontal slot 33. Vertical slots 82 and 83 may alternately extend only on one side of the horizontal slots and then on the other side of the horizontal slots. FIG. 13 shows section 102 of a lead frame 1300 with a keyhole structure in lead post 85 that (like lead post 80 of FIG. 8A) includes a pair of horizontal slots (e.g., horizontal slots 31 and 33). The horizontal slots extend horizontally inward in the x direction from the right edge R and the left edge L of the lead post toward a middle portion 32 of the lead post. In lead post 85, as shown in FIG. 13, vertical slots 82 that are open to horizontal slots 31 and 33 extend upward (in the y direction) from the upper edges UE of the horizontal slots. Further, vertical slots 83 that are open to horizontal slots 31 and 33 extend downward (in the minus y direction) from the lower edges LE of the horizontal slots. Vertical slots 82 alternate in position with vertical slots 83 along the x direction as they intersect (or open to) the horizontal slots.

The vertical slots 82 may have a height h7 above the upper edges UE of the horizontal slots and the vertical slots 83 may have a height h8 below the lower edges LE of the horizontal slots. Including the width (Sw) of the horizontal slot (e.g., slot 31 or slot 33), the vertical slots 82 may have a height=Sw+h7, and the vertical slots 83 may have a height=Sw+h8. A range of heights covered by the arrangement of vertical slots in lead post 85 may enable a more accurate y-axis positioning of the flexibly-aligned clip in a semiconductor package.

In the foregoing, FIGS. 9A, 10A, 11A and 12A illustrate examples of semiconductor die 410 and source contact pads 44 disposed at various locations on paddle 110 of lead frame 800 (FIG. 8). The source contact pads 44 shown in these FIGS. 9A, 10A, 11A and 12A. are connected by flexibly-aligned clip 200 to lead post 80 of lead frame 800. FIGS. 9A, 10A, 11A, and 12A show, for example, semiconductor die 410 disposed at a distance D1, D2, D3 and D4, respectively, from a right edge R of paddle 110, Further, as shown in FIGS. 9A, 10A, 11A and 12A, semiconductor die 410 may be disposed at height h1, h2, h3 and h4, respectively, from a bottom edge BE of paddle 110.

In example implementations, lead frame 800 may be replaced by lead frame 1300 having the keyhole structure in lead post 85 shown in FIG. 13. Keys 218 in key structure 220 of clip 200 (FIG. 2B) can be placed in either vertical slots 82 or vertical slots 83 in lead post 85 to control y-axis positioning of the flexibly-aligned clip in a semiconductor package.

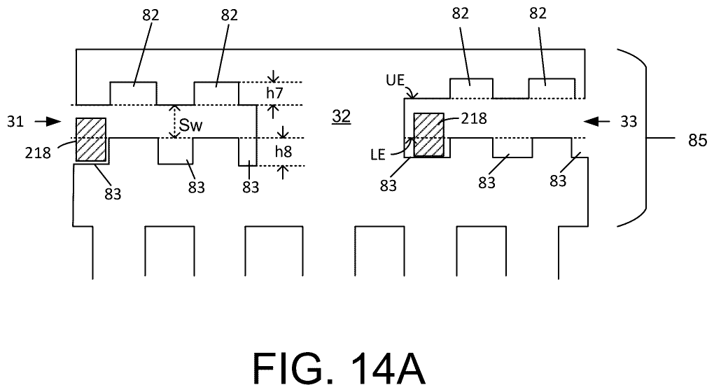

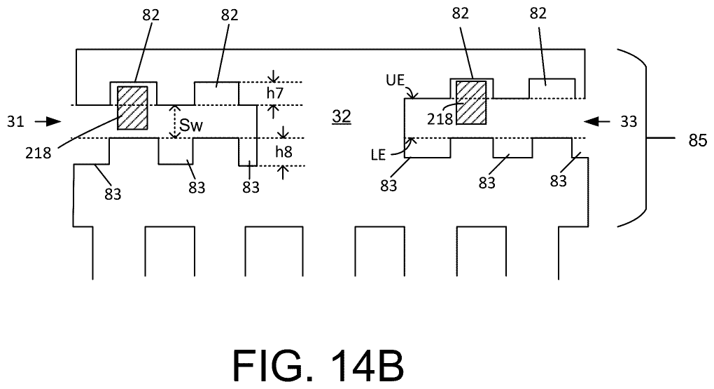

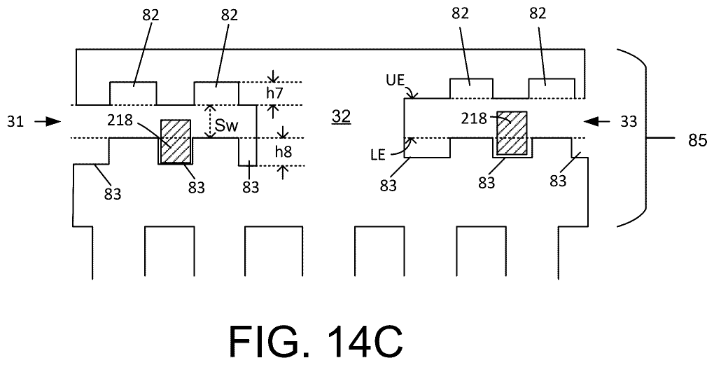

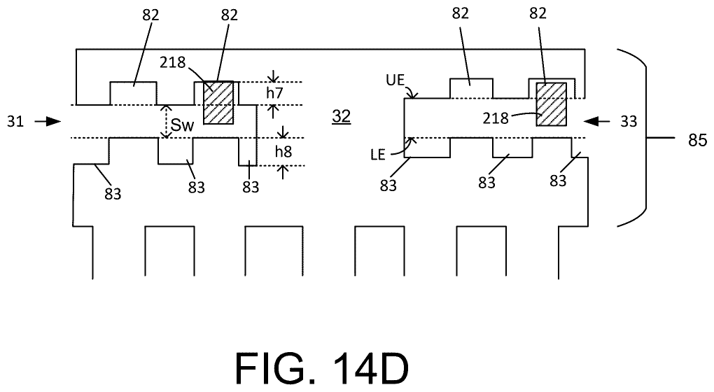

FIG. 14 A, 14B, 14C and 14D show a cross-sectional view of lead post 85 and keys 218 of key structure 220 (in the x-y plane of lead post 85) for various configurations of the semiconductor die 410 and paddle 110 shown in FIGS. 9A, 10A, 11A, and 12A, respectively.

FIG. 14 A corresponds to the example of semiconductor die 410 disposed at a distance D1 from right edge R of paddle 110 (FIG. 9A). FIG. 14A shows that keys 218 of clip 200 may be placed in vertical slots 83 along the lower edges LE of horizontal slots 31 and 33 to control y-axis positioning of the flexibly-aligned clip in a semiconductor package.

FIG. 14B corresponds to the example of semiconductor die 410 disposed at a distance D2 from right edge R of paddle 110 (FIG. 10A). FIG. 14B shows that keys 218 of clip 200 may be placed in vertical slots 82 along the upper edges UE of horizontal slots 31 and 33 to control y-axis positioning of the flexibly-aligned clip in a semiconductor package.

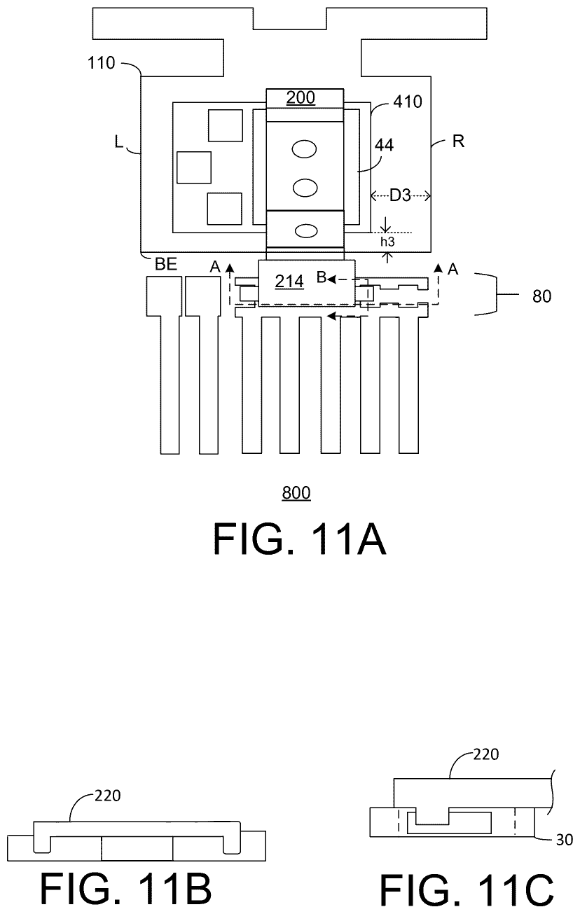

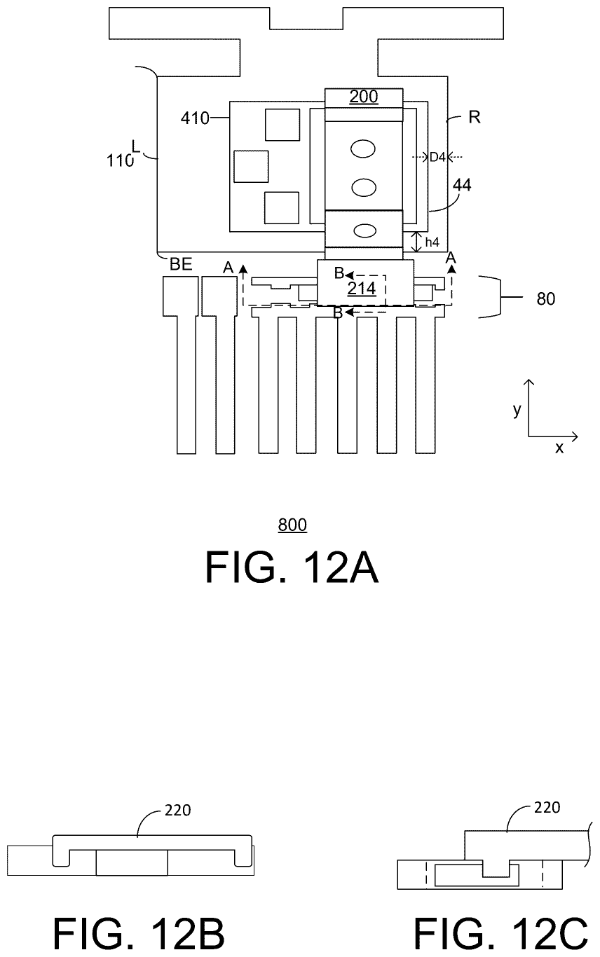

FIG. 14C corresponds to the example of semiconductor die 410 disposed at a distance D3 from right edge R of paddle 110 (FIG. 11A). FIG. 14C shows that keys 218 of clip 200 may be placed in vertical slots 83 along the lower edges LE of horizontal slots 31 and 33 to control y-axis positioning of the flexibly-aligned clip in a semiconductor package.

FIG. 14D corresponds to the example of semiconductor die 410 disposed at a distance D4 from right edge R of paddle 110 (FIG. 12A). FIG. 14D shows that keys 218 of clip 200 may be placed in vertical slots 82 along the upper edges UE of horizontal slots 31 and 33 to control y-axis positioning of the flexibly-aligned clip in a semiconductor package.

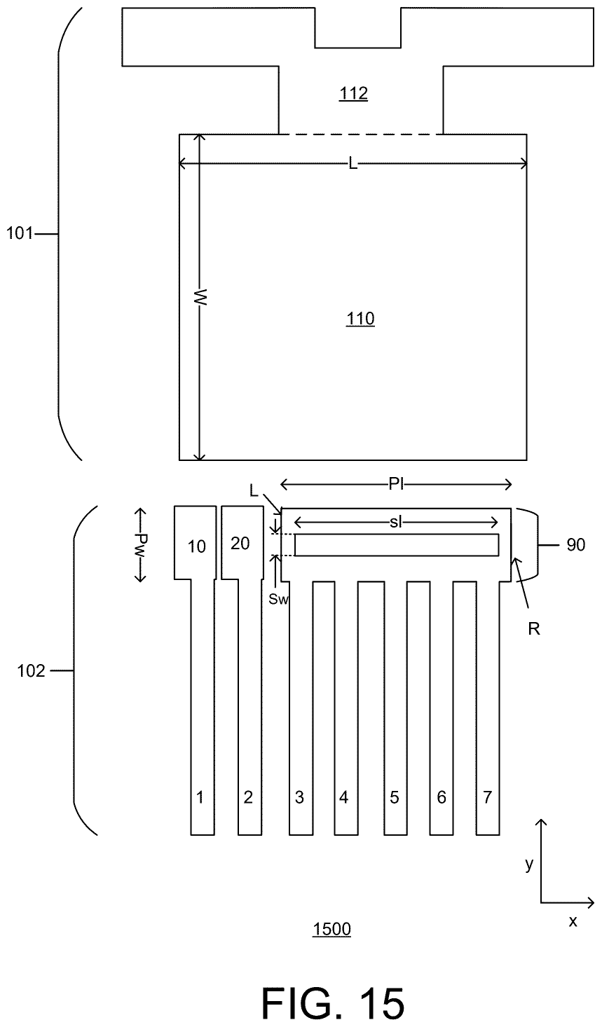

FIG. 15 shows a plan view that is yet another example lead frame 1400 that can be used in a semiconductor die package. Lead frame 1500, like lead frame 100 (FIG. 1), may include a first section 101 and a second section 102.

Second section 102 of lead frame 1500, like lead frame 100 (FIG. 1), may include a plurality of leads (e.g., lead 1, lead 2, lead 3, lead 4, lead, 5, lead 6, and lead 7, etc.) that may, for example, form the external signal leads of the semiconductor die package. The lead posts of the various leads may be coupled to the device contact pads (e.g., gate contact pad, signal sense contact pad, Kelvin contact pad, and source contact pad, etc.) in the semiconductor die mounted on paddle 110 by wire bonds or clip connections. Leads 3-7 may share a common lead post 90.

In example implementations, lead post 90 may include a keyhole structure allowing the lead post to be connected by a flexibly-aligned clip (e.g., clip 200, FIGS. 2A and 2B) to the source contact pad on the semiconductor die (e.g., source contact pad 44 of semiconductor die 410, FIG. 3B) mounted on paddle 110.

In example implementations, lead post 90 in lead frame 1500 may have a rectangular shape having a length Pl (in the x direction) and a width Pw (in the y direction). In example implementations, lead post 90 may include a keyhole structure configured to receive the pair of spaced-apart keys, prongs, or stubs of the flexibly-aligned clip (e.g., clip 200, FIGS. 2A and 2B). The keyhole structure may, for example, include a single slot 91 extending horizontally (in the x direction) from about a right edge R of the lead post to about a left edge L of the lead post. Slot 91 may have a rectangular shape with a width Sw in the y direction and length sl in the x direction. In example implementations, the width Sw of slot 91 may be about one third or less than a third of the width PW of lead post 90.

FIG. 16 is a flow chart illustrating an example method 1600 for packaging a semiconductor die.

Method 1600 includes disposing a semiconductor die at a variable location on a paddle in a lead frame (1610). The semiconductor die may include a source contact pad. Disposing a semiconductor die on the paddle may include disposing the semiconductor die on a layer of solder (e.g., a solder pad). The semiconductor die may wind up in a variable location on the paddle, for example, after solder reflow.

Method 1600 further includes aligning a clip to connect a lead post of the lead frame to the source contact pad on semiconductor die disposed at the variable location on the paddle (1620). In example implementations of method 1500, aligning the clip 1620 may include coupling one end of the clip to a clip locking feature in the lead post.

The clip may, for example, include a key structure. The key structure may, for example, include at least a pair of keys extending perpendicular to a plane of the clip. Further, aligning the clip includes placing the pair of keys in at least one slot of the clip locking feature in the lead post.

In example implementations, aligning the clip to connect the lead post of lead frame 1620 includes soldering a first portion of the clip to the source contact pad and soldering a second portion of the clip to a portion of the lead post.

Method 1600 further comprises: encapsulating the semiconductor die, the clip, and a portion of the lead frame in a molding compound (1630).

In example implementations, a package may include (e.g., enclose) multiple semiconductor die disposed on a lead frame structure. The multiple die may include die made of a same semiconductor material (e.g., silicon or silicon carbide), or in the case of a hybrid multi-die package, the multiple dies may include die made of different semiconductor material (e.g., silicon and silicon carbide).

In some implementations, one or more of the multiple semiconductor die may be connected to corresponding lead posts leading to the external terminals of the package. In example implementations, the one or more of the multiple semiconductor die may be connected to a corresponding one or more of the lead posts using one or more clips (e.g., flexibly-aligned clip 200) in conjunction with clip-locking features (keyhole structures) in the lead posts (e.g., lead posts 30, 80, 85, and 90) as described in the foregoing with reference to FIG. 1 to FIG. 16.

In some example implementations, one or more of the multiple semiconductor die (that are not connected by the flexibly-aligned clips (e.g., flexibly-aligned clip 200) to keyhole structures in the lead posts) may be connected to respective lead posts (e.g., lead posts 30, 80, 85, and 90) using clips (non-flexibly-aligned clips), wire bonding, and/or solder ball grid arrays.

For example, a first semiconductor die can be connected to the flexibly-aligned clip (as described herein (e.g., flexibly-aligned clip 200)) and a second semiconductor die can be connected to, for example, a lead post (e.g., lead posts 30, 80, 85, and 90) using a clip. As another example, a first semiconductor die can be connected to the flexibly-aligned clip (as described herein) and a second semiconductor die can be connected to, for example, a lead post using wire bonding. As yet another example, a first semiconductor die can be connected to the flexibly-aligned clip (as described herein) and a second semiconductor die can be connected to, for example, a lead post using a solder ball grid array.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A package comprising:
a semiconductor die disposed on a lead frame;
a source contact pad disposed on the semiconductor die;
a lead post shared by a plurality of leads that form external terminals of the package, the lead post having a clip-locking feature; and
a clip connecting the source contact pad to the lead post, the clip having a key structure coupled to the clip-locking feature in the lead post.

2. The package of claim 1, further comprising a mold body encapsulating the semiconductor die and at least a portion of the lead frame.

3. The package of claim 1, wherein a first end of the clip is bonded to the source contact pad and a second end of the clip is bonded to the lead post.

4. The package of claim 3, wherein a coupling of the key structure in the clip and the clip-locking feature in the lead post aligns a position of the clip relative to a position of the source contact pad on the semiconductor die.

5. The package of claim 1, wherein the clip is a strip of metal, and wherein the key structure includes a pair of spaced-apart protrusions, the pair of protrusions including keys, prongs or stubs extending perpendicularly to a plane the clip.

6. The package of claim 5, wherein the clip-locking feature in the lead post is a hole structure that is cut in the lead post and configured to receive the pair of spaced-apart protrusions of the clip.

7. The package of claim 6, wherein the hole structure comprises a first slot extending horizontally from an edge of the lead post toward a center of the lead post, and a second slot extending horizontally from an opposite edge of the lead post toward the center of the lead post, the first slot and the second slot being separated by an intermediate uncut portion of the lead post.

8. The package of claim 7, wherein the hole structure further comprises at least one vertical slot extending perpendicularly across the first slot and at least another one vertical slot extending perpendicularly across the second slot.

9. The package of claim 7, wherein the hole structure further comprises:
at least one vertical slot opening into the first slot along an upper edge of the first slot and extending perpendicularly away from the first slot; and
at least one second vertical slot opening into the first slot along a lower edge of the first slot and extending perpendicularly away from the first slot.

10. The package of claim 9, wherein the at least one vertical slot opening into the first slot along an upper edge of the first slot and the at least one second vertical slot opening into the first slot along a lower edge of the first slot alternate in position along a length of the first slot.

11. The package of claim 6, wherein the hole structure comprises a single slot extending horizontally from one side of the lead post to a second side of the lead post along a length of the lead post.

12. The package of claim 1, wherein the lead frame comprises a flat plate or sheet made of copper, a copper-alloy, or an iron-nickel alloy.

13. The package of claim 1, wherein the clip is made of copper, a copper-alloy, or an iron-nickel alloy.

14. The package of claim 1, wherein the semiconductor die includes a silicon carbide (SiC) power transistor.

15. A package comprising:
a semiconductor die disposed at a variable location on a paddle in a lead frame, the semiconductor die including a source contact pad; and
a clip connecting the source contact pad to a lead post of the lead frame forming an external terminal of the package, the clip being aligned relative to the variable location of the semiconductor die on the paddle and the lead post.

16. The package of claim 15, wherein the lead post includes a keyhole structure configured to receive a key structure of the clip and to hold the clip in an aligned position.

17. A method comprising:
disposing a semiconductor die at a variable location on a paddle in a lead frame, the semiconductor die including a source contact pad; and
aligning a clip to connect a lead post of the lead frame to the source contact pad on the semiconductor die disposed at the variable location on the paddle.

18. The method of claim 17, wherein aligning the clip includes coupling one end of the clip to a clip locking feature in the lead post.

19. The method of claim 18, wherein a key structure includes at least a pair of protrusions extending perpendicular to a plane of the clip, and wherein flexibly aligning the clip includes placing the pair of protrusions in at least one slot of the clip locking feature in the lead post.

20. The method of claim 19, wherein flexibly aligning the clip to connect the lead post of lead frame includes bonding a first portion of the clip to the source contact pad and bonding a second portion of the clip to a portion of the lead post.

21. The method of claim 17 further comprising: encapsulating the semiconductor die, the clip, and a portion of the lead frame in a molding compound.
